(19) United States
(12) Patent Application Publication
(10) Pub. No.: US 2026/0020498 A1
(43) Pub. Date: Jan. 15, 2026

(54) PROCESS FOR FABRICATING A PIEZOELECTRIC OR SEMICONDUCTOR STRUCTURE

(71) Applicant: Soitec, BERNIN (FR)

(72) Inventors: Cédric Charles-Alfred, BERNIN (FR); Alexis Drouin, BERNIN (FR); Isabelle Huyet, BERNIN (FR); Stéphane Thieffry, Bernin (FR); Marcel Broekaart, BERNIN (FR); Thierry Barge, BERNIN (FR)

(21) Appl. No.: 18/881,121

(22) PCT Filed: Jul. 7, 2023
(86) PCT No.: PCT/FR2023/051048

§ 371 Date: Jan. 3, 2025

(30) Foreign Application Priority Data
Jul. 7, 2022 (FR) FR2206980

(51) Int. Cl. H10N 30/072; H01L 21/762

(52) U.S. Cl. CPC H10N 30/072; H01L 21/76254

(57) ABSTRACT

A process for fabricating a semiconductor or piezoelectric structure comprises the following successive steps: (a) providing a donor substrate comprising a piezoelectric or semiconductor layer, (b) providing a receiver substrate, (c) treating a free surface of the donor substrate and/or a free surface of the receiver substrate, (d) bonding the donor substrate to the receiver substrate, the at least one treated free surface being at the interface between the donor substrate and the receiver substrate, and (e) transferring a portion of the piezoelectric or semiconductor layer from the donor substrate to the receiver substrate. The treatment of the free surface of the donor substrate and/or of the free surface of the receiver substrate comprises the following successive steps: (c1) chemical-mechanical polishing, and (c2) removing material from a peripheral region of the polished surface.

### CROSS-REFERENCE TO RELATED APPLICATIONS

This application is a national phase entry under 35 U.S.C. § 371 of International Patent Application PCT/FR2023/051048, filed Jul. 7, 2023, designating the United States of America and published as International Patent Publication WO 2024/009046 A1 on Jan. 11, 2024, which claims the benefit under Article 8 of the Patent Cooperation Treaty of French Patent Application Serial No. FR2206980, filed Jul. 7, 2022.

### TECHNICAL FIELD

The present disclosure relates to a process for fabricating a semiconductor or piezoelectric structure.

### BACKGROUND

The transfer of an active layer, that is a layer intended for the formation of components for electronic, optical or opto-electronic devices, to a carrier substrate by way of an electrically insulating layer, is widely used in the microelectronics industry.

In some cases, the active layer is obtained by thinning a donor substrate, this thinning being performed by removal of matter, such as by grinding. To improve the surface finish of the active layer before bonding, it is generally necessary to carry out chemical mechanical polishing (CMP).

This is the case, in particular, for the fabrication of a radiofrequency (RF) device, such as a resonator or filter, on a substrate comprising, successively, from its base to its surface, a carrier substrate, generally made of a semiconductor material such as silicon, an electrically insulating layer and a piezoelectric layer.

The piezoelectric layer is typically obtained by transferring a thick substrate made of a piezoelectric material to a carrier substrate.

Transfer of the piezoelectric layer entails bonding the thick piezoelectric substrate to the carrier substrate, followed by thinning the thick piezoelectric substrate so as to leave only a thin piezoelectric layer on the carrier substrate, this layer having the thickness desired for the fabrication of the RF device.

To obtain good adhesion of the piezoelectric substrate to the carrier substrate, a layer of oxide (for example, a silicon oxide) is generally formed on each of the two substrates, and the substrates are bonded by way of the oxide layers.

The oxide layer formed at the surface of the carrier substrate may be formed by thermal oxidation. For example, if it is a silicon substrate, a silicon oxide layer may thus be formed. However, thermal oxidation has a number of drawbacks. It may be incompatible with certain materials, for example, with layers for trapping charge made of polycrystalline silicon. Furthermore, thermal oxidation generates oxide layers, which do not allow good diffusion, for example, of lithium or hydrogen.

Thus, deposition of an oxide layer by PECVD is often preferred to thermal oxidation. The oxide layer may then be polished, for example, by chemical mechanical polishing.

To strengthen the oxide-oxide bonding between the piezoelectric substrate and the carrier substrate, it is known practice to carry out, after bonding, consolidation annealing. The consolidation annealing is typically carried out at a temperature of between 100° C. and 300° C.

However, since the piezoelectric material and the material of the carrier substrate have very different thermal expansion coefficients, implementing such annealing may cause the assembly to deform substantially.

To overcome this type of problem, it is known practice to use a pseudo-donor substrate, that is to say a heterostructure in which the piezoelectric substrate is bonded to a handle substrate.

The process for fabricating the pseudo-donor substrate generally comprises a number of steps. Thus, a thick layer made of a piezoelectric material is bonded to the handle substrate. Next, the layer made of piezoelectric material is thinned and optionally trimmed. Lastly, the free surface of the thinned layer made of piezoelectric material is polished, for example, in a chemical mechanical polishing (CMP) process and optionally covered with a thin oxide layer so as to carry out the oxide-oxide bonding mentioned above.

After bonding the pseudo-donor substrate and the carrier substrate, the piezoelectric substrate is held between the handle substrate and the carrier substrate. The choice of materials and thicknesses of the handle substrate and of the carrier substrate makes it possible to ensure a certain symmetry of the thermal expansion coefficients, and thus to minimize the deformation of the assembly during the application of heat treatments.

However, when implementing such a process for fabricating a structure of piezoelectric-on-insulator type, the applicants have observed defects in the bonding between the pseudo-donor substrate and the carrier substrate, in the form of voids, referred to as “edge bonding voids,” in which bonding does not occur at the periphery of the substrates.

### BRIEF SUMMARY

One aim of the present disclosure is to improve, during the fabrication of a structure of active-layer-on-insulator type, the process of bonding between a donor substrate and a receiver substrate, the surface to be bonded of the donor substrate and/or the surface to be bonded of the receiver substrate having been polished prior to the bonding.

To that end, the present disclosure proposes a process for fabricating a semiconductor or piezoelectric structure, comprising the following steps in succession:
(a) providing a donor substrate comprising a semiconductor or piezoelectric layer,
(b) providing a receiver substrate,
(c) treating a free surface of the donor substrate and/or a free surface of the receiver substrate,
(d) bonding the donor substrate to the receiver substrate, the at least one treated surface being at the interface between the donor substrate and the receiver substrate, and
(e) transferring a portion of the semiconductor or piezoelectric layer (5) from the donor substrate to the receiver substrate,
the treatment of the free surface of the donor substrate and/or of the free surface of the receiver substrate comprising the following steps in succession:
(c1) chemical mechanical polishing,
(c2) removal of matter in a peripheral region of the polished surface.

The removal of matter in a peripheral region of the surface to be bonded of one and/or the other of the substrates polished beforehand makes it possible to improve the flatness of the surface prior to bonding such that the bonding quality is thereby improved.

According to other features of the present disclosure, which are optional, and which may be implemented alone, or in combination when this is technically possible:
at the end of the step of chemical mechanical polishing of the donor substrate and/or of the receiver substrate (c1), the polished surface has a relief at the periphery of the substrate, such that the step of removal of matter (c2) in the peripheral region of the surface is carried out to planarize the relief,
the removal of peripheral matter is carried out by milling with an ion beam focused on an area of the periphery of the polished semiconductor or piezoelectric layer, the ion beam scanning the whole of the periphery,
the removal of peripheral matter is carried out after recording the topographical profile of the polished surface by profilometry and is performed such that the modified profile after removal of matter has only one maximum and the maximum is the point closest to the center of the polished surface of the modified profile,
the portion of the semiconductor or piezoelectric layer of the donor substrate to be transferred to the receiver substrate is delimited by formation of a weakened region prior to bonding (d) of the donor substrate to the receiver substrate, such that the transfer of the portion to the receiver substrate comprises detaching the donor substrate along the weakened region,
the weakened region in the donor substrate is formed by implanting hydrogen and/or helium,
the donor substrate comprises a piezoelectric layer, the surface of the donor substrate to be treated and to be bonded being a free surface of the piezoelectric layer and the portion of the donor substrate transferred being a portion of the piezoelectric layer,
the provision of the donor substrate comprises the following steps in succession:
   (a1) bonding a thick piezoelectric layer to a handle substrate,
   (a2) thinning the thick piezoelectric layer from the side thereof opposite the handle substrate,
such that the chemical mechanical polishing (c1) is carried out on the free surface of the thinned piezoelectric layer, opposite the handle substrate,
the thick piezoelectric layer has a thickness of between 100 μm and 2 mm, preferably a thickness of between 200 μm and 1 mm and the thinned and polished piezoelectric layer has a thickness of between 1 μm and 100 μm, preferably a thickness of between 5 μm and 50 μm,
the provision of the donor substrate further comprises a step (a3) of removal of a peripheral portion of the donor substrate prior to chemical mechanical polishing (c1) of the free surface of the thinned piezoelectric layer,
the donor substrate comprises a semiconductor layer, the surface of the donor substrate to be treated and to be bonded being a free surface of the semiconductor layer and the portion of the donor substrate transferred being a portion of the semiconductor layer,
the process further comprises a step of formation of an oxide layer on the free surface of the semiconductor or piezoelectric layer, such that bonding (d) of the donor substrate to the receiver substrate is carried out by way of the oxide layer,
the oxide layer formed at the surface of the polished semiconductor or piezoelectric layer has a thickness of between 10 nm and 10 μm, preferably a thickness of between 30 nm and 5 μm,
the step (c) comprises a treatment of the free surface of the semiconductor or piezoelectric layer of the donor substrate and the formation of the oxide layer on the free surface is carried out after the treatment step (c) and prior to bonding (d),
the provision of the receiver substrate (b) comprises the formation of an electrically insulating layer, preferably an oxide layer, the surface of the receiver substrate to be treated and to be bonded being a free surface of the electrically insulating layer,
the electrically insulating layer formed at the surface of the receiver substrate has a thickness of between 10 nm and 10 μm, preferably a thickness of between 30 nm and 5 μm,
the electrically insulating layer is formed by plasma-enhanced chemical vapor deposition (PECVD),
the step of removal of matter (c2) is carried out over the whole of the polished surface of the receiver substrate,
the quantity of matter to be removed locally at the surface of the electrically insulating layer during the step of removal of matter at the surface of the electrically insulating layer is determined on the basis of measurements of the thickness of the electrically insulating layer by ellipsometry and/or reflectometry.

### BRIEF DESCRIPTION OF THE DRAWINGS

Other features and advantages of the present disclosure will become apparent from the following detailed description, with reference to the appended drawings, in which:

FIG. 1 shows a cross-sectional view of a multilayer structure of piezoelectric-on-insulator type prepared according to an embodiment of the process according to the present disclosure comprising the bonding of a donor substrate to a receiver substrate;

FIG. 2 shows a cross-sectional view of the donor substrate;

FIG. 3 shows a cross-sectional view of a step in the preparation of the donor substrate comprising bonding of a thick piezoelectric layer to a handle substrate;

FIG. 4 shows a cross-sectional view of a step in the preparation of the donor substrate comprising thinning of the thick piezoelectric layer bonded to the handle substrate;

FIG. 5 shows the peripheral relief observed on the surface of the thinned piezoelectric layer opposite the handle substrate after an additional step of chemical mechanical polishing;

FIG. 6 shows a cross-sectional view of the receiver substrate;

FIG. 7 shows a cross-sectional view of a step in the preparation of the receiver substrate comprising bonding of an electrically insulating layer to a carrier substrate;

FIG. 8 shows a cross-sectional view of the formation of a weakened region in the thinned piezoelectric layer of the donor substrate;

FIG. 9 shows a cross-sectional view of the bonding of the donor substrate to the receiver substrate;

FIG. 10 shows a cross-sectional view of the formation of a weakened region in the thinned piezoelectric layer of the donor substrate, the donor substrate further comprising an oxide layer formed beforehand on the free surface, optionally polished and planarized, of the thinned piezoelectric layer; and

FIG. 11 shows a cross-sectional view of the bonding of the donor substrate to the receiver substrate, when the donor substrate further comprises the oxide layer on the thinned piezoelectric layer, on the opposite side to the handle substrate.

For the sake of legibility, the drawings have not necessarily been drawn to scale.

### DETAILED DESCRIPTION

The present disclosure relates to a process for fabricating multilayer components, comprising transferring an active layer from a donor substrate to a receiver substrate.

To improve the quality of bonding between the donor substrate and the receiver substrate during the implementation of the transfer, it may be favorable to carry out, prior to the bonding, chemical mechanical polishing of at least one of the two surfaces forming the bonding interface if the surface is too rough to promote good bonding. This is, for example, the case where one of the bonding surfaces has been formed during thinning of a layer by grinding. Nevertheless, the multilayer structures resulting from such a process have many voids at their periphery, at their bonding interface, which impair the quality of bonding between the active layer transferred and the receiver substrate.

It has been found that, during the fabrication of such multilayer structures, microdroplets of condensation water get trapped at the periphery of the substrates, when the substrates are bonded, at the limit of propagation of the bonding wave. It is suspected that these condensation microdroplets cause the voids visible in the final multilayer structures.

It has also been found that the free surfaces of the substrates, which have been polished by chemical mechanical polishing have a relief, in the form of an overthickness, on their periphery. It is suggested that it is this peripheral relief that traps the condensation water at the periphery of the substrates during bonding thereof, which generates the voids observed in the final multilayer structure.

In this regard, the present disclosure relates to a process for fabricating a multilayer structure comprising transferring an active layer from a donor substrate to a receiver substrate, at least one of the two bonding interfaces having been polished prior to bonding of the two substrates, the process further comprising a step of removal of peripheral matter on at least one of the two polished surfaces.

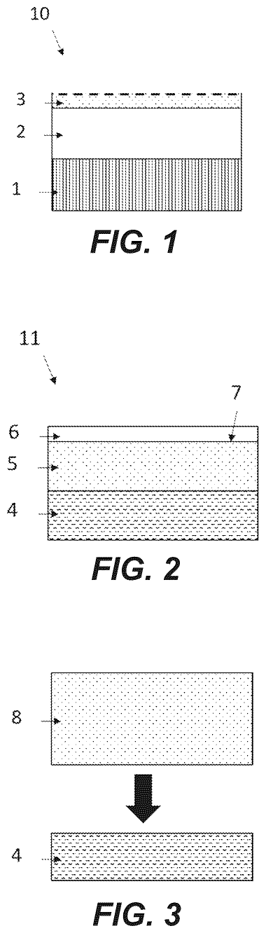

A particular embodiment of the present disclosure is described below, in which a multilayer piezoelectric-on-insulator structure 10 shown in FIG. 1 is prepared, the structure comprising in succession, from its rear face to its front face:
a carrier substrate 1,
an electrically insulating layer 2, preferably an oxide layer, and
a piezoelectric layer 3.

By way of example, the piezoelectric layer 3 is made of a material such as lithium tantalate (LiTaO₃), lithium niobate (LiNbO₃), barium titanate (BaTiO₃) and/or lead zirconate titanate (PZT). The piezoelectric layer 3 has a thickness of between 50 nm and 20 μm, preferably a thickness of between 100 nm and 10 μm.

The electrically insulating layer 2 may comprise a silicon oxide, nitride and/or carbide (SiOₓ, SiOₓN_{y}, SiNₓ, SiCₓ, SiOₓC_{y}), x and y being real numbers between 0 and 2, and/or polymers. The electrically insulating layer has a thickness of between 10 nm and 10 μm, preferably a thickness of between 30 nm and 5 μm.

Lastly, the carrier substrate 1 is, for example, a substrate made of silicon (Si), sapphire, alumina (Al₂O₃), aluminum nitride (AlN), glass, quartz, mullite, molybdenum (Mo), tungsten (W), indium phosphide (InP), gallium arsenide (GaAs) and/or silicon carbide (SiC). The carrier substrate 1 has a thickness of between 10 μm and 2 mm, preferably a thickness of between 200 μm and 1 mm.

Such piezoelectric-on-insulator structures 10 are used in the field of radiofrequency components and filters.

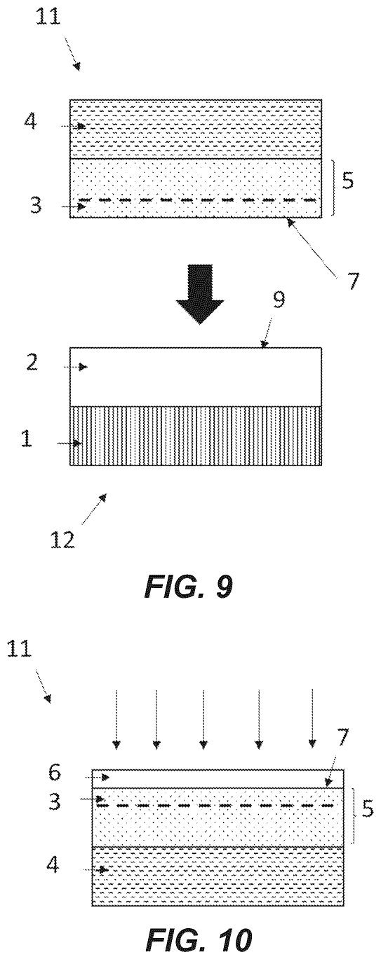

In this particular embodiment, the process according to the present disclosure comprises the provision of a donor substrate 11 comprising a piezoelectric layer 3 to be transferred, the provision of a receiver substrate 12 comprising the carrier substrate 1 and the electrically insulating layer 2, and the transfer of the piezoelectric layer 3 to be transferred from the donor substrate 11 to the receiver substrate 12, the electrically insulating layer 2 being at the bonding interface (see FIG. 9).

According to this embodiment, the donor substrate 11 shown in FIG. 2 is a heterostructure commonly referred to as a virtual donor substrate, which comprises, from its rear face to its front face:
a handle substrate 4, and
a thinned piezoelectric layer 5 in which the piezoelectric layer 3 to be transferred to the receiver substrate 12 will be delimited, and
optionally, an electrically insulating layer 6, which is preferably an oxide layer.

The piezoelectric material of the piezoelectric layer 3 and the material of the carrier substrate 1 have very different thermal expansion coefficients. The deposition of a layer made of piezoelectric material without a handle substrate on the carrier substrate, with an electrically insulating layer at the interface, would expose the resulting multilayer structure to considerable deformation when carrying out thermal annealing, for example, to strengthen the bonding interface between the layer made of piezoelectric material and the carrier substrate.

The handle substrate 4 is thus made of a material having a thermal expansion coefficient close to that of the material of the carrier substrate 1 to which the piezoelectric layer 3 is intended to be transferred. The term “close” is understood to mean a difference in thermal expansion coefficient between the material of the handle substrate 4 and the material of the carrier substrate 1 of less than or equal to 5% and preferably equal to or in the vicinity of 0%. Suitable materials are, for example, silicon, sapphire, polycrystalline aluminum nitride, or gallium arsenide. Preferably, the handle substrate 4 is made of the same material as the carrier substrate 1. In the present disclosure, it is the thermal expansion coefficient in a plane parallel to the main surface of the substrates that is of interest. The handle substrate 4 has a thickness of between 100 μm and 2 mm, preferably a thickness of between 200 μm and 1 mm. Preferably, the handle substrate 4 has a thickness close to that of the carrier substrate 1, so that the structure obtained after bonding of the donor substrate 11 to the receiver substrate 12 is as symmetrical as possible and as balanced as possible in terms of mechanical and thermal behavior. A thermal expansion coefficient and a thickness of the handle substrate 4 that are close to the thermal expansion coefficient and the thickness, respectively, of the carrier substrate 1 make it possible to minimize the stresses on the multilayer structure and its deformation under the effect of temperature fluctuations.

The electrically insulating layer 6 is, for example, a silicon oxide, nitride and/or carbide (SiOₓ, SiOₓN_{y}, SiNₓ, SiCₓ, SiOₓC_{y}) layer, x and y being real numbers between 0 and 2, and/or a polymer. The electrically insulating layer 6 has a thickness of between 10 nm and 10 μm, preferably a thickness of between 30 nm and 5 μm.

### Provision of the Donor Substrate and Optional Treatments of a Free Surface of the Donor Substrate

As shown in FIG. 3, the formation of the donor substrate 11 comprises bonding of a thick piezoelectric layer 8 to a handle substrate 4.

The thick piezoelectric layer 8 has a thickness of between 100 μm and 2 mm, preferably a thickness of between 200 μm and 1 mm. The thick piezoelectric layer 8 is formed of the piezoelectric material, which constitutes the piezoelectric layer 3 in the final piezoelectric-on-insulator structure 10. The thick piezoelectric layer 8 may thus comprise LiTaO₃, LiNbO₃, BaTiO₃ and/or PZT.

Bonding of the thick piezoelectric layer 8 to the handle substrate 4 is, for example, carried out with the aid of a photo-polymerizable adhesive layer deposited beforehand on an exposed face of the handle substrate 4 or of the thick piezoelectric layer 8. The photo-polymerizable adhesive layer is advantageously deposited by spin-coating. Bonding by a photo-polymerizable adhesive layer has the advantage of including fewer fabrication steps than molecular bonding. Furthermore, the polymer, which is initially liquid, will smooth over flatness defects and partially compensate for the lower edge resulting from chamfering of the substrates. Bonding by a photo-polymerizable adhesive layer thus makes it possible to bond the substrates closer to their periphery than molecular bonding.

Alternatively, bonding of the thick piezoelectric layer 8 to the handle substrate 4 is carried out by molecular bonding, bonding by molecular milling under ultra-high vacuum, or metal/metal bonding by thermocompression.

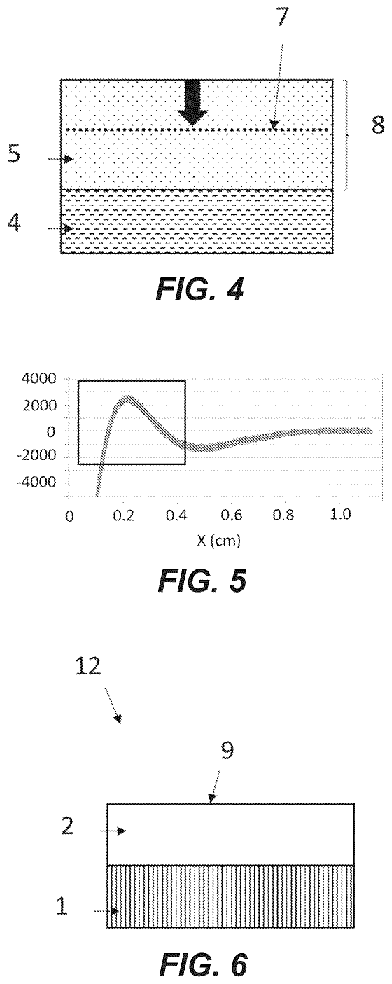

After bonding of the thick piezoelectric layer 8 to the handle substrate 4, the thick piezoelectric layer 8 is thinned from the side thereof opposite the handle substrate, as shown in FIG. 4, such that the thinned piezoelectric layer 5 has a thickness of between 1 μm and 100 μm, preferably a thickness of between 5 μm and 50 μm.

Thinning of the thick piezoelectric layer 8 is, for example, carried out by coarse grinding, which makes it possible to rapidly reduce the thickness of the donor substrate 11. Next, finer grinding may be carried out to continue to reduce the thickness of the donor substrate 11, while decreasing the roughness of the surface of the donor substrate 11.

Lastly, chemical mechanical polishing (CMP) is carried out to smooth the free surface 7 of the thinned piezoelectric layer 5 opposite the handle substrate 4, in such a way as to achieve the desired roughness for bonding of the pseudo-donor substrate 11 to the receiver substrate 12 and thus improve the quality of bonding.

Prior to chemical mechanical polishing, the process may further comprise a step of trimming of the piezoelectric layer 8, 5. The trimming step may be implemented before, during (for example, between two grinding operations with different degrees of fineness) or after the step of thinning of the piezoelectric layer 8, 5. Trimming comprises removal of peripheral matter over at least the thickness of the piezoelectric layer 8, 5.

The thick piezoelectric layer 8 has a peripheral chamfer C on each of its main faces (not shown in the figures). The purpose of the trimming step is to get rid of the sharp angle created by thinning of the donor substrate 11 at the chamfer when the thickness e of the thinned piezoelectric layer 5 is smaller than the thickness of the chamfer C of the thinned piezoelectric layer 5 and to create a right (or obtuse) angle. To be specific, such a sharp angle is likely to break off during handling of the donor substrate 11, give rise to flaking, and contaminate the production line with debris.

Trimming may be carried out with the aid of a grinding wheel, for example, a diamond wheel, rotated about an axis Y, the donor substrate 11 being itself attached to a support rotated about an axis X, wherein the axis Y may be parallel or perpendicular to the axis X.

Whatever the technique used, trimming may give rise to defects that the chemical mechanical polishing can partially rectify.

Chemical mechanical polishing makes it possible to obtain a free surface 7 of the thinned piezoelectric layer 5 having a roughness compatible with bonding to the receiver substrate 12. However, at the end of such a step of chemical mechanical polishing, it is noticed that the polished surface 7 of the thinned piezoelectric layer 5 has a peripheral relief. FIG. 5 shows an analysis by profilometry of the surface 7. The profilometry analysis is performed with the aid of a probe, the vertical movement of which is recorded during scanning of the surface 7, in such a way as to obtain the topographical profile of the surface along the path taken by the probe. Profilometry of the surface 7 thus makes it possible to reveal the abovementioned peripheral relief (black square in FIG. 5).

The less flat the profile, the more negative the impact is on bonding. The process according to the present disclosure therefore comprises removal of matter in the peripheral region of the surface.

The step of removal of matter in the peripheral region of the polished surface 7 of the thinned piezoelectric layer 5 is preferably carried out in such a way as to planarize the peripheral relief formed during the step of chemical mechanical polishing. The aim is to prevent, during bonding to the receiver substrate 12, the relief from trapping condensation water and from obstructing removal of this water under the effect of the propagation of the bonding wave.

It has been observed that the peripheral relief may be several micrometers thick and several millimeters wide and that the dimensions of the relief depend on the grinding parameters (such as the speeds of rotation of the grinder and of the grinding plate, the speed of descent and the inclination of the grinder) and on the chemical mechanical polishing parameters (such as the distribution of the pressure applied to the plates, the hydrodynamics of the colloidal slurry used, the speed of relative rotation of the polishing head and of the platen). It is in fact very difficult to decorrelate the effect of each of these parameters on the characteristics of the resulting peripheral relief and hence to identify values of parameters that do not lead to the formation of such a relief. The removal of peripheral matter according to the present disclosure provides a solution unrelated to the thinning and polishing process, which makes it possible to get rid of the peripheral relief whatever the grinding parameters and chemical mechanical polishing parameters used.

The removal of peripheral matter may be carried out by milling with an ion beam focused on an area of the periphery of the surface 7 of the thinned and polished piezoelectric layer 5, the ion beam scanning the whole of the periphery. When ion-beam milling is used it is possible to set a number of parameters, such as the width of the beam, the angle of incidence, the current (corresponding to the flow of ions constituting the beam), the scanning speed (defining the time for which an area of the surface is located beneath the beam) and the milling speed (corresponding to the speed of removal of the matter), so as to control the removal of peripheral matter very precisely. It is in fact possible to modulate the milling speed down to very low values (around 10⁻³ m³/s). The combined control of the milling speed and the scanning speed makes it possible to achieve precision of the surface profile to within a nanometer.

Ion-beam milling is a technique conventionally used to adjust the thickness of a piezoelectric substrate in order to improve its performance. The present disclosure proposes using this technique to rectify the topology of the surface of the substrate and improve the flatness thereof. Ion-beam milling has the advantage of making it possible to correct the profile of the surface with sufficient precision to prevent the removal of too much matter and the formation of a recess. Indeed, such a recess would also affect the quality of bonding between the donor substrate and the receiver substrate by increasing the width of the peripheral surface over which the substrates are not properly bonded, this surface conventionally being formed during the bonding of two substrates, in particular, owing to the chamfers of the two substrates.

In practice, the topographical profile is first recorded by profilometry. Next, the thickness to be removed is determined in such a way that the modified profile has only one maximum, hence a zero deviation point, and that this point is the point closest to the center of the substrate (the point furthest to the right of the profiles in FIG. 5).

Lastly, optionally, the formation of the donor substrate 11 shown in FIG. 2 further comprises a step of formation of the electrically insulating layer 6 on the free surface 7 of the thinned piezoelectric layer 5, on the side opposite the handle substrate 4. In the event of chemical mechanical polishing followed by removal of a peripheral portion of the surface 7, the electrically insulating layer 6 is preferably formed after these treatments on the thinned piezoelectric layer 5, which has been polished and planarized.

The electrically insulating layer 6 is preferably formed by plasma-enhanced chemical vapor deposition (PECVD) or by physical vapor deposition (PVD).

According to an alternative embodiment of the present disclosure not developed herein, the donor substrate comprises a semiconductor layer, the surface of the donor substrate to be treated (by chemical mechanical polishing and by peripheral removal of matter) and to be bonded being a free surface of the semiconductor layer and the portion of the donor substrate transferred being a portion of the semiconductor layer. In this embodiment too, laser-beam milling ensures removal of peripheral matter with very great precision.

Also according to this embodiment, an oxide layer may be formed on the free surface of the semiconductor layer, the layer possibly having been treated beforehand by chemical mechanical polishing and removal of peripheral matter.

According to this embodiment, the process makes it possible to obtain a multilayer structure of semiconductor-on-insulator type by transfer of the semiconductor layer to a receiver substrate such as the substrate 12.

### Provision of a Receiver Substrate and Optional Treatments of the Free Surface of the Receiver Substrate

According to the embodiment described in detail here, the receiver substrate 12 shown in FIG. 6 comprises, from its rear face to its front face:
a carrier substrate, which forms the carrier substrate 1 in the final piezoelectric-on-insulator structure 10, and
an electrically insulating layer, which forms the electrically insulating layer 2 in the final piezoelectric-on-insulator structure 10.

The carrier substrate 1 is thus made of a material such as silicon (Si), sapphire, alumina (Al₂O₃), aluminum nitride (AlN), glass, quartz, mullite, molybdenum (Mo), tungsten (W), indium phosphide (InP), gallium arsenide (GaAs) and/or silicon carbide (SiC). The carrier substrate 1 has a thickness of between 10 μm and 2 mm, preferably a thickness of between 200 μm and 1 mm.

The electrically insulating layer 2 comprises, for example, a silicon oxide, nitride and/or carbide (SiOₓ, SiOₓN_{y}, SiNₓ, SiCₓ, SiOₓC_{y}), x and y being real numbers between 0 and 2, and/or a polymer. The electrically insulating layer 2 of the receiver substrate has a thickness of between 10 nm and 10 μm, preferably a thickness of between 30 nm and 5 μm.

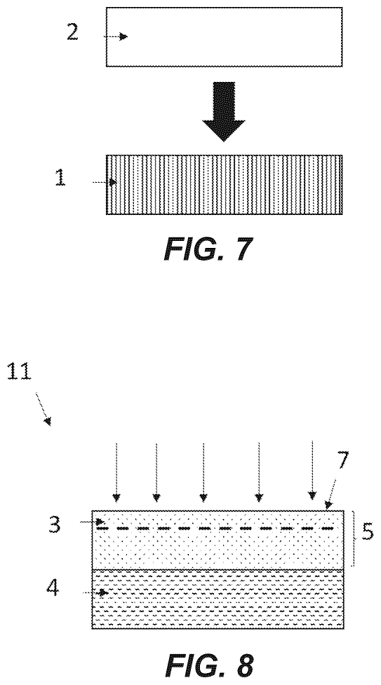

The provision of the receiver substrate 12 comprises the formation of the electrically insulating layer 2 on a free surface of the carrier substrate 1, in such a way as to obtain the receiver substrate 12. The electrically insulating layer 2 is preferably formed by plasma-enhanced chemical vapor deposition (PECVD). Such a deposition is depicted in FIG. 7. The PECVD process gives rise to significant non-uniformity and roughness, which are not compatible with good quality bonding. Moreover, even if other deposition processes may give better results in terms of uniformity and roughness, excessive roughness of the electrically insulating layer may also result from the free surface of the carrier substrate, for example, when the carrier substrate comprises at its surface a layer of polycrystalline silicon, which has not been planarized.

Chemical mechanical polishing of the free surface 9 of the electrically insulating layer 2 opposite the carrier substrate 1 is thus carried out.

Also in this case, the formation of a peripheral relief on the free surface 9 of the electrically insulating layer 2 at the end of polishing has been observed, the relief being up to several hundred nanometers thick and several millimeters wide. It has been further observed that these dimensions vary depending on the parameters used when implementing the chemical mechanical polishing, such as the hydrodynamics of the colloidal slurry used, the distribution of the pressure applied to the plates and the speed of relative rotation of the chemical mechanical polishing head and platen. The process according to the present disclosure therefore comprises, in addition to chemical mechanical polishing, removal of matter in the peripheral region.

The removal of matter in the peripheral region of the surface is preferably carried out to planarize the relief, whatever the parameters used when implementing the chemical mechanical polishing.

Just as described above, the removal of peripheral matter is preferably carried out by milling with an ion beam focused on an area of the periphery of the polished surface 9 of the electrically insulating layer 2, the ion beam scanning the whole of the periphery. In practice, as for the planarization of the surface 7 of the thinned and polished piezoelectric layer 5, a topographical profile of the polished surface 9 of the electrically insulating layer 2 is first recorded by profilometry. Next, the thickness to be removed is determined in such a way that the modified profile has only one maximum, hence a zero deviation point, and that this point is the point closest to the center of the substrate.

Optionally, the step of removal is carried out over the whole of the polished surface 9 of the receiver substrate 12, in such a way as to improve the uniformity of the electrically insulating layer 2. In this case, the quantity of matter to be removed locally at the surface 9 of the electrically insulating layer 2 during the step of removal of matter on the surface 9 may be determined on the basis of measurements of the local thickness of the electrically insulating layer 2 by ellipsometry and/or reflectometry.

### Transfer of a Portion of the Donor Substrate to the Receiver Substrate

Next, a portion 3 of the thinned piezoelectric layer 5 of the donor substrate 11 is transferred to the receiver substrate 12.

By way of example, the transfer may comprise forming a weakened region in the thinned piezoelectric layer 5, in such a way as to delimit the piezoelectric layer 3 to be transferred, bonding the donor substrate 11 to the receiver substrate 12, the piezoelectric layer 3 to be transferred being at the bonding interface, and detaching the donor substrate 11 along the weakened region.

According to a preferred embodiment shown in FIG. 8, the weakened region is formed by implantation of atomic species in the thinned piezoelectric layer 5, the implantation (arrows in FIG. 8) being carried out through the free surface 7 of the piezoelectric layer 5. The atomic species are implanted at a predetermined depth, this depth determining the thickness of the piezoelectric layer 3 to be transferred. The atomic species implanted are preferably hydrogen and/or helium.

Next, bonding of the donor substrate 11 to the receiver substrate 12, as shown in FIG. 9, is carried out between the free surface 7 of the thinned piezoelectric layer 5 that has been subject to implantation and the free surface 9 of the electrically insulating layer 2 of the receiver substrate 12, at least one of the two bonding surfaces 7, 9 having undergone the abovementioned surface treatment beforehand, the treatment comprising chemical mechanical polishing followed by peripheral removal of matter.

Bonding of the donor substrate 11 to the receiver substrate 12 is preferably carried out by molecular adhesion, as this makes it possible to obtain bonding that is mechanically strong and stable at a temperature above 400° C. Such bonding properties are particularly beneficial when the portion 3 of the thinned piezoelectric layer 5 of the donor substrate 11 is transferred to the receiver substrate 12 in accordance with the SMART CUT™ process (which comprises the formation of a weakened region by implantation of atomic species). To be specific, the SMART CUT™ process generates in the substrate defects that can be remedied by thermal annealing at high temperature. Such bonding properties cannot be achieved by bonding with a polymer or by metal/metal bonding. The vast majority of polymers break down completely above 300° C. Metal/metal bonding evolves with temperature (increase in the grain size) and, most of the time, leads to deformation of the substrate, not to mention the diffusion of metal atoms in the layers, which disrupts the electrical properties of the starting stack.

Molecular bonding requires an extremely flat surface since any lack of flatness prevents close contact between the two substrates, thus resulting in bonding defects, which, subsequently, will lead to missing parts in the transferred surface. The present disclosure thus affords a particular advantage in this embodiment and in any embodiment in which bonding between a donor substrate and a receiver substrate is preferably carried out by molecular adhesion.

In this embodiment, at the time of bonding, the formation of microdroplets of water at the end of the bonding wave, at the periphery of the substrates, was not observed.

After bonding, the donor substrate 11 is detached along the weakened region. Detachment along the weakened region may be triggered by a mechanical action and/or a supply of thermal energy.

The final piezoelectric-on-insulator structure 10 shown in FIG. 1 is thus obtained, this comprising, from the rear face to the front face, the carrier substrate 1, the electrically insulating layer 2 and the transferred piezoelectric layer 3.

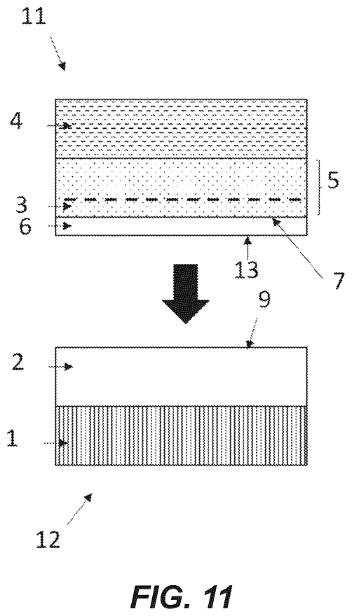

In the case where an oxide layer 6 has been formed at the surface of the donor substrate 11, the implantation of atomic species shown in FIG. 10 is carried out through the oxide layer 6 and the bonding shown in FIG. 11 is carried out between the free surface 13 of the oxide layer 6 and the free surface 9 of the electrically insulating layer 2 of the receiver substrate 12, such that the oxide layer 6 is transferred at the same time as the piezoelectric layer 3 to be transferred. In this embodiment, the electrically insulating layer of the final structure comprises the oxide layer 6 formed on the donor substrate 11 prior to bonding.

The formation of an electrically insulating layer 6 at the surface of the donor substrate 11 thus advantageously allows oxide-oxide bonding. In the case where bonding by molecular adhesion is carried out, the bonding between two oxide layers may easily be strengthened simply by bringing the bonding to a temperature above 200° C. Furthermore, in an atmosphere with some degree of moisture, the oxide layers make it possible to absorb the water naturally present at their surface and thus to prevent this water from forming gas bubbles at the bonding interface when the bonding is annealed at above 200° C. to strengthen same.

As an alternative to the SMART CUT™ process described above, the layer transfer may be achieved by thinning the donor substrate from the side thereof opposite the side bonded to the handle substrate, until the thickness desired for the first semiconductor layer is obtained. However, the SMART CUT™ process is preferred for transferring layers less than one micrometer thick.

An analysis of fault detection by laser scanning reveals that the final structure of piezoelectric-on-insulator type 10 has almost no voids between the piezoelectric layer 5 and the electrically insulating layer 2 at the periphery of the structure. In particular, when molecular bonding is carried out, every particle at the bonding interface gives rise to a void. As the periphery is more sensitive to the presence of particles, the few voids still detected at the periphery after implementation of the process according to the present disclosure are attributed not to microdroplets of water at the end of the bonding wave at the time of bonding of the two layers (these being moreover not observed), but to the presence of particles at the bonding interface.

It is believed that it is the removal of peripheral matter on bonding surfaces having undergone polishing that makes it possible to eliminate the relief created at the edge during the polishing prior to bonding of the surfaces, and that, therefore, condensation water is not retained at the periphery of the substrates during the propagation of the bonding wave, which prevents the formation of microdroplets. Bonding quality is thereby improved since the number of voids is much lower in the final structure.

The process according to the present disclosure thus makes it possible to improve the quality of bonding between two substrates in a process in which chemical mechanical polishing of at least one of the two bonding surfaces was necessary prior to the bonding.

1. A method of fabricating a semiconductor or piezoelectric structure, comprising successively:
(a) providing a donor substrate comprising a semiconductor or piezoelectric layer;
(b) providing a receiver substrate;
(c) treating a free surface of at least one of the donor substrate and the receiver substrate to form at least one treated surface;
(d) bonding the donor substrate to the receiver substrate, the at least one treated surface being at an interface between the donor substrate and the receiver substrate; and
(e) transferring a portion of the semiconductor or piezoelectric layer from the donor substrate to the receiver substrate;
wherein treating the free surface of at least one of the donor substrate and the receiver substrate comprises successively:
(c1) chemical mechanical polishing of the free surface to form a polished surface; and
(c2) removal of matter in a peripheral region of the polished surface.

2. The method of claim 1, wherein at the end of the chemical mechanical polishing, the polished surface has a relief at the periphery of the donor or receiver substrate, such that the removal of matter in the peripheral region of the surface is carried out to planarize the relief.

3. The method of claim 1, wherein the removal of peripheral matter is carried out by milling with an ion beam focused on an area of the periphery of the polished semiconductor or piezoelectric layer, the ion beam scanning the whole of the periphery.

4. The method of claim 1, wherein the removal of matter is carried out after recording a topographical profile of the polished surface by profilometry and is performed such that a modified profile after removal of matter has only one maximum and the maximum is a point closest to the center of the polished surface of the modified profile.

5. The method of claim 1, wherein the portion of the semiconductor or piezoelectric layer of the donor substrate to be transferred to the receiver substrate is delimited by formation of a weakened region prior to bonding (d) of the donor substrate to the receiver substrate, such that the transfer of the portion to the receiver substrate comprises detaching the donor substrate along the weakened region.

6. The method of claim 5, wherein the weakened region in the donor substrate is formed by implanting at least one of hydrogen and helium.

7. The method of claim 1, wherein the donor substrate comprises a piezoelectric layer, the surface of the donor substrate to be treated and to be bonded being a free surface of the piezoelectric layer and the portion of the donor substrate transferred being a portion of the piezoelectric layer.

8. The method of claim 7, wherein providing the donor substrate comprises successively:
(a1) bonding a thick piezoelectric layer to a handle substrate; and
(a2) thinning the thick piezoelectric layer from a side opposite the handle substrate,
such that the chemical mechanical polishing (c1) is carried out on the free surface of the thinned piezoelectric layer, opposite the handle substrate.

9. The method of claim 8, wherein the thick piezoelectric layer has a thickness of between 100 μm and 2 mm, preferably a thickness of between 200 μm and 1 mm and, after the chemical mechanical polishing (c1), the thinned piezoelectric layer has a thickness of between 1 μm and 100 μm, preferably a thickness of between 5 μm and 50 μm.

10. The method of claim 8, wherein providing the donor substrate further comprises removal (a3) of a peripheral portion of the donor substrate prior to chemical mechanical polishing (c1) of the free surface of the thinned piezoelectric layer.

11. The method of claim 1, wherein the donor substrate comprises a semiconductor layer, the surface of the donor substrate to be treated and to be bonded being a free surface of the semiconductor layer and the portion of the donor substrate transferred being a portion of the semiconductor layer.

12. The method of claim 7, further comprising forming an electrically insulating layer on a free surface of the piezoelectric layer, such that bonding (d) of the donor substrate to the receiver substrate is carried out by way of the electrically insulating layer.

13. The method of claim 12, wherein the electrically insulating layer has a thickness of between 10 nm and 10 μm, preferably a thickness of between 30 nm and 5 μm.

14. The method of claim 12, wherein the step (c) comprises a treatment of the free surface of the semiconductor or piezoelectric layer of the donor substrate and wherein the formation of the electrically insulating layer on the free surface is carried out after the treatment step (c) and prior to bonding (d).

15. The method of claim 1, wherein providing the receiver substrate (b) comprises forming an electrically insulating layer, preferably an oxide layer, the surface of the receiver substrate to be treated and to be bonded being a free surface of the electrically insulating layer.

16. The method of claim 15, wherein the electrically insulating layer formed on the receiver substrate has a thickness of between 10 nm and 10 μm, preferably a thickness of between 30 nm and 5 μm.

17. The method of claim 15, wherein the electrically insulating layer is formed by plasma-enhanced chemical vapor deposition (PECVD).

18. The method of claim 15, wherein the removal of matter (c2) is carried out over the whole of the polished surface of the receiver substrate.

19. The method of claim 18, wherein a quantity of matter to be removed locally at the surface of the electrically insulating layer during the removal of matter (c2) is determined on a basis of measurements of a thickness of the electrically insulating layer by at least one of ellipsometry and reflectometry.

20. The method of claim 11, further comprising forming an electrically insulating layer on the free surface of the semiconductor layer, such that bonding (d) of the donor substrate to the receiver substrate is carried out by way of the electrically insulating layer.

21. The method of claim 20, wherein the electrically insulating layer has a thickness of between 10 nm and 10 μm, preferably a thickness of between 30 nm and 5 μm.

22. The method of claim 21, wherein step (c) comprises treating a free surface of the semiconductor layer and wherein forming the electrically insulating layer on the free surface is carried out after the treatment step (c) and prior to bonding (d).
